(19) United States
(12) Patent Application Publication
(10) Pub. No.: US 2008/0122078 A1
(43) Pub. Date: May 29, 2008

(54) Systems and methods to passivate on-die redistribution interconnects

(76) Inventors: Jun He, Portland, OR (US); Kevin J. Lee, Beaverton, OR (US); Kaustabh Gadre, Portland, OR (US); Subhash Joshi, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/595,645

(22) Filed: Nov. 8, 2006

(51) Int. Cl. H01L 23/488; H01L 21/44

(52) U.S. Cl. 257/737; 438/613; 257/E23.023; 257/E21.476

(57) ABSTRACT

An integrated circuit apparatus comprises a semiconductor substrate having a plurality of devices formed thereon, one or more metallization layers to interconnect the plurality of devices, and a bond pad formed over the one or more metallization layers and electrically coupled to at least one of the metallization layers. A first passivation layer is formed over the bond pad and over the metallization layers and a redistribution interconnect formed on the passivation layer. A first via formed through the first passivation layer electrically couples the redistribution interconnect to the bond pad. A second passivation layer is formed on the redistribution interconnect to prevent thermomechanical degradation and improve electromigration performance. A dielectric layer is formed on the second passivation layer and a die-side bump is formed on the dielectric layer. A second via formed through the dielectric layer and through the second passivation layer electrically couples the die-side bump to the redistribution interconnect.

### BACKGROUND

When an integrated circuit (IC) die, also known as an “IC chip”, is manufactured, it is typically packaged before it is sold. The package provides electrical connections to the chip's internal circuitry, protection from the external environment, and heat dissipation functionality. In one package system, an IC die is flip-chip connected to a motherboard substrate. In a flip-chip package, also known as a controlled-collapse chip connection (C4), electrical leads on the IC die, known as die-side bumps, are distributed on its active surface and the active surface is electrically connected to corresponding leads, known as solder bumps, on a motherboard substrate.

As is known in the art, the IC die includes a device layer upon which transistors are formed, as well as multiple metallization layers to interconnect the transistors. Each metallization layer includes metal interconnects and vias that are electrically insulated by a low-k dielectric material. Some IC dies further include a redistribution layer formed between the final metallization layer and the die-side bumps. The redistribution layer is an additional metal layer for electrical interconnect on which the connections from the original bond pads of the final metallization layer are redistributed over the surface of the die to the die-side bumps of the IC chip. This rerouting of power and/or signal lines enables the die-side bumps to correctly match up with the solder bumps on the motherboard substrate.

The redistribution layer may include thick copper interconnect layers that cannot be formed economically using a traditional dual damascene process due to their large dimensions. As such, conventional processes to form barrier layers for dual damascene copper interconnects are unavailable. Redistribution layer interconnects therefore remain unpassivated and tend to show degraded thermomechanical and electromigration performance. Accordingly, improved processes are needed to passivate redistribution layer interconnects.

### BRIEF DESCRIPTION OF THE DRAWINGS

FIG. 1 illustrates an integrated circuit die.

FIG. 2 is a method for forming passivated redistribution interconnects in accordance with an implementation of the invention.

FIGS. 3A to 3K illustrate various structures that are formed when the method of FIG. 2 is carried out.

FIG. 4 is a method for forming passivated redistribution interconnects in accordance with another implementation of the invention.

FIGS. 5A to 5C illustrate various structures that are formed when the method of FIG. 4 is carried out.

FIG. 6 is a method for forming passivated redistribution interconnects in accordance with another implementation of the invention.

FIGS. 7A to 7D illustrate various structures that are formed when the method of FIG. 6 is carried out.

FIG. 8 is a method for forming passivated redistribution interconnects in accordance with another implementation of the invention.

FIGS. 9A to 9C illustrate various structures that are formed when the method of FIG. 8 is carried out.

### DETAILED DESCRIPTION

Described herein are systems and methods of passivating redistribution layer interconnects (referred to herein simply as redistribution interconnects). In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

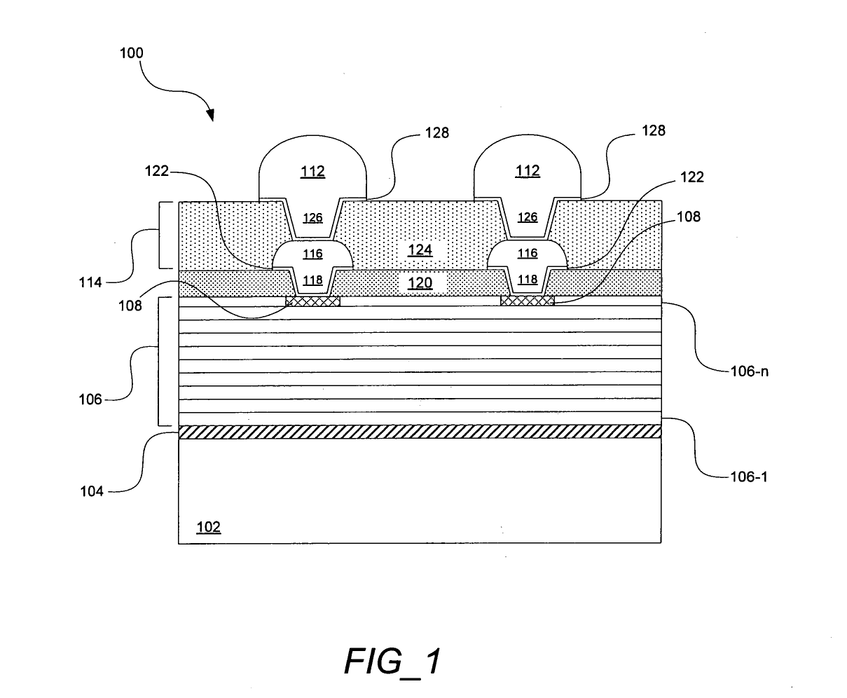

FIG. 1 illustrates an integrated circuit (IC) die 100. The IC die 100 is built on a portion of a semiconductor substrate 102. The substrate 102 may be formed using a bulk silicon or a silicon-on-insulator substructure. In other implementations, the substrate 102 may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate 102 may be formed are described here, any material that may serve as a foundation upon which a semiconductor device may be built falls within the spirit and scope of the present invention.

A top surface of the substrate 102 provides a device layer 104, upon which transistors, as well as other devices such as capacitors and inductors, may be formed. Above the device layer 104 are multiple metallization layers 106-1 through 106-n, where n represents the total number of metallization layers. Conventional IC dies can have as few as one metallization layer to as many as ten metallization layers, although greater than 10 metallization layers are also possible. Each metallization layer 106 includes metal interconnects, generally formed of copper, as well as vias that electrically couple metal interconnects across various metallization layers. Each metallization layer 106 also includes interlayer dielectric (ILD) material surrounding and insulating the metal interconnects and the vias. ILD materials that may be used include, but are not limited to, silicon dioxide (SiO₂), carbon-doped oxide (CDO), silicon nitride (SiN), organic polymers such as perfluorocyclobutane (PFCB), or fluorosilicate glass (FSG).

On the final metallization layer 106-n are a number of bond pads 108. One or more interconnects of the metallization layers 106 terminate at the bond pads 108, which are generally formed of copper or aluminum. A passivation layer 120 is formed above the metallization layers 106 to seal and protect the IC die 100 and the metallization layers 106 from damage and contamination. The passivation layer 120 may be formed from many different materials, including but not limited to silicon nitride (SiN), oxynitride, polyimide, and certain polymers. Openings may be formed in the passivation layer 120 to expose the bond pads 108.

Each bond pad 108 is electrically coupled to a die-side bump 112 by way of a redistribution layer 114. The redistribution layer 114 can reroute a bond pad 108 to a die-side bump 112 that is not necessarily above or proximate to that bond pad 108. The redistribution layer 114 includes one or more redistribution interconnects 116 that are used for the rerouting. The use of the redistribution layer 114 enables the layout of the bond pads 108 to be appropriately reconfigured to match the layout of a motherboard substrate to which the IC die 100 is being flip-chip connected.

Each bond pad 108 is directly coupled to its redistribution interconnect 116 through a via 118. An opening for the via 118 may be formed in the passivation layer 120. A base layer metallurgy (BLM) layer 122, which typically includes a barrier layer and a seed layer, may be formed in the opening, and the via 118 may be formed on the BLM layer 122 using a plating process. The same plating process may be used further to form the redistribution interconnect 116 on the via 118. The plating process may be an electroplating (EP) process or an electroless (EL) plating process, as are known in the art.

An ILD layer 124 may be formed over the redistribution interconnect 116. Dielectric materials that may be used to form the ILD layer 124 include the same materials described above for the ILD material used in the metallization layers 106. Again, these materials include SiO₂, CDO, SiN, PFCB, or FSG. In further implementations, the material used to form the ILD layer 124 may include one or more of the following: rubbers such as silicone rubber, various butyl rubbers, and so on, polybenzoxazole, polybenzimidazole, polyetherimide, polyhydantoin, polyimides, certain polyamides e.g., aramids such as NOMEX and KEVLAR (NOMEX and KEVLAR are registered trademarks of E.I. du Pont de Nemours and Company, Wilmington, Del.), certain polycarbonates and certain polyesters, novolak resins and poly(hydroxystyrene) (PHS) available commercially under the trade name WPR including WPR-1020, WPR-1050, and WPR-1201 (WPR is a registered trademark of JSR Corporation, Tokyo, Japan), benzocyclobutene (BCB) available under the trade name CYCLOTENE (CYCLOTENE is a registered trademark of Dow Chemical Co., Midland, Mich.), poly(acrylate) also available under the trade name WPR, poly(methacrylate), alicyclic polymers such as UNITY polynorbornene (UNITY is a registered trademark of Promerus, LLC, Brecksville, Ohio) and epoxy such as SU-8 available commercially from MICROCHEM (MICROCHEM is a registered trademark of MicroChem Corp., Newton, Mass.).

A die-side bump 112 may be formed atop the ILD layer 124 and may be coupled to the redistribution interconnect 116 by way of a via 126. An opening in the ILD layer 124 may be formed to enable fabrication of the via 126. As with the redistribution interconnect 116, a BLM layer 128 may first be formed in the opening prior to formation of the via 126 and the die-side bump 112.

The die-side bumps 112 provide the final electrical connection between the metallization layers 106 and the environment outside of the IC die 100. The die-side bumps 112 are generally formed using a metal such as copper, a copper alloy, or an alloy of lead and tin. In a typical C4 process, the solder bumps on a motherboard substrate or other carrier are aligned with the die-side bumps 112 and are reflowed to form joints. The die-side bumps 112 generally fill several important functions. For example, because it is very difficult to directly attach electrical wires between a motherboard substrate and thin, small bond pads 108, die-side bumps 112 provide a medium through which such connections can be made. Furthermore, die-side bumps 112 provide a standoff that can produce a controlled gap between the IC die 100 and a motherboard substrate. If the interconnect length is close to zero, any thermal expansion mismatch will cause extreme stress concentrations. The die-side bumps 112 act as a short lead to relieve these stresses.

As described above, the redistribution interconnects 116 are large and thick relative to copper interconnects found within the metallization layers 106. As such, conventional dual damascene processes used to form the copper interconnects within the metallization layers 106 cannot be used as a cost effective way to form the redistribution interconnects 116. Likewise, conventional processes for forming barrier layers that are compatible with dual damascene processes cannot be applied to the redistribution interconnects 116 using the process flow described above. The redistribution interconnects 116 therefore tend to remain unpassivated, and as a result, they tend to show degraded thermomechanical and electromigration performance.

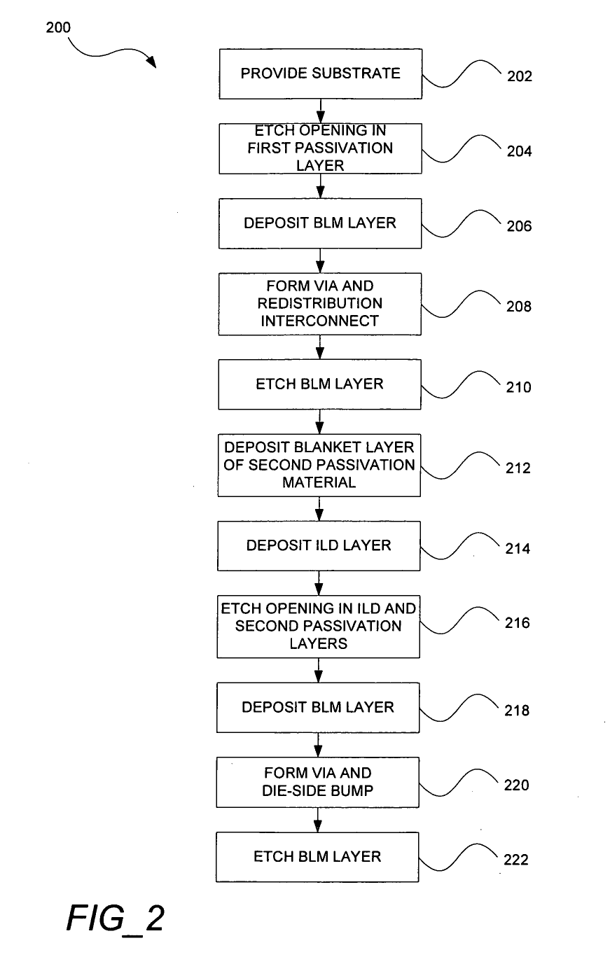

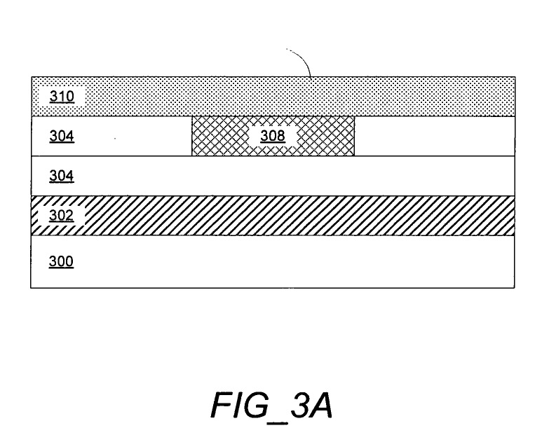

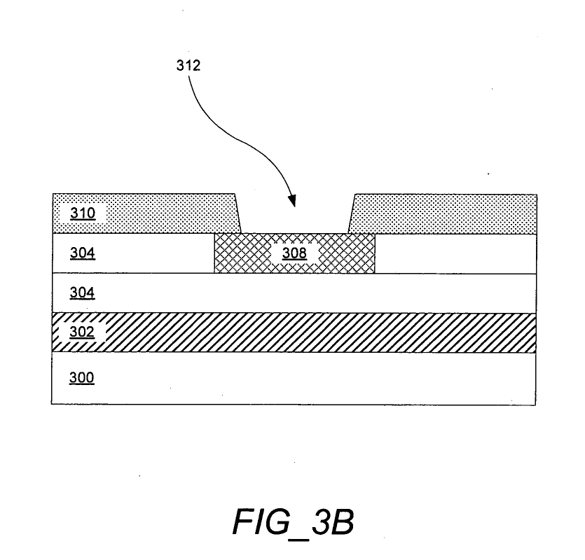

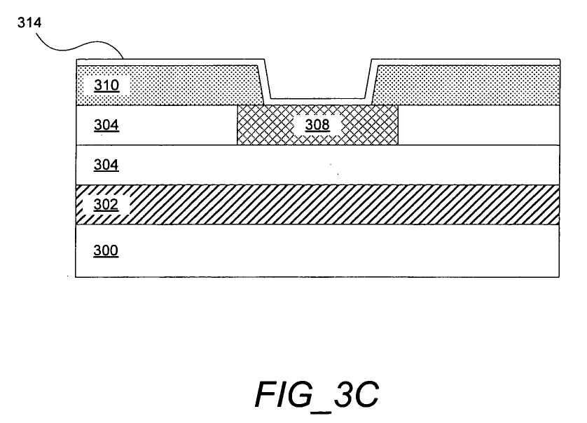

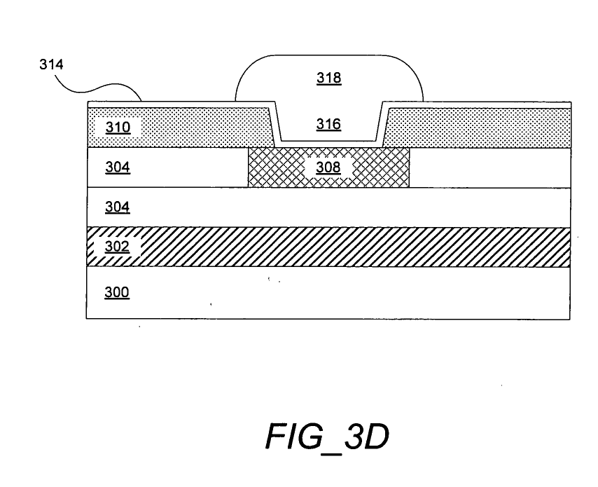

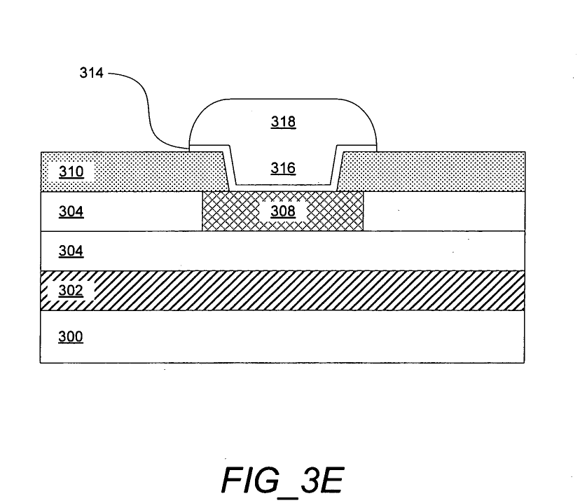

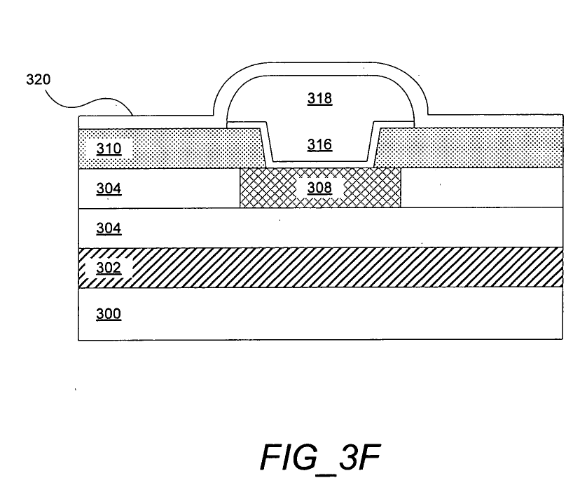

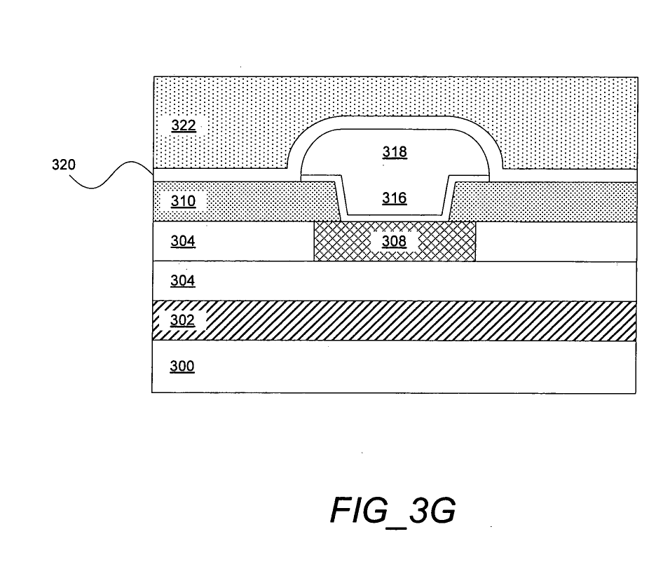

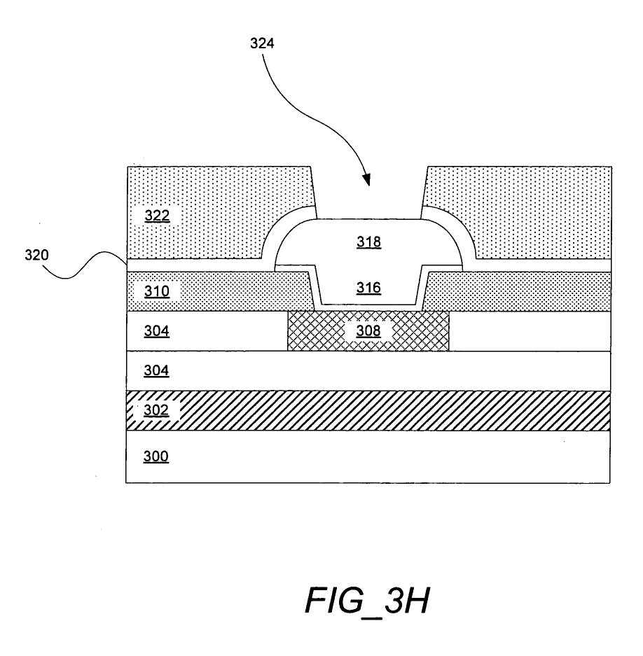

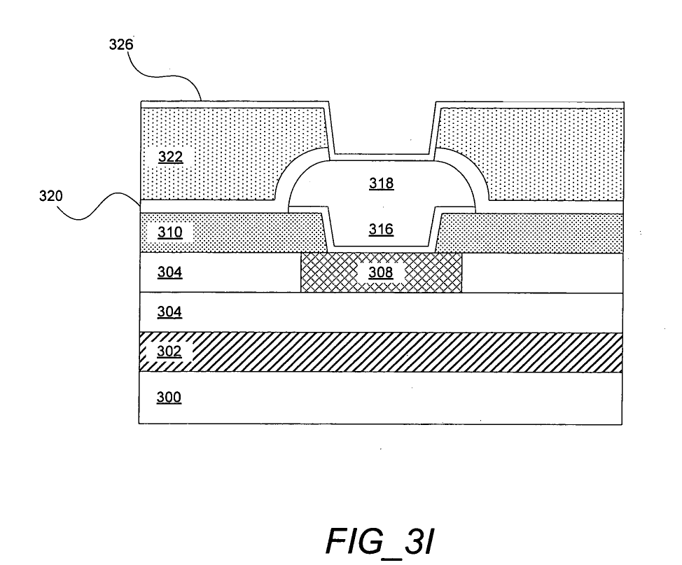

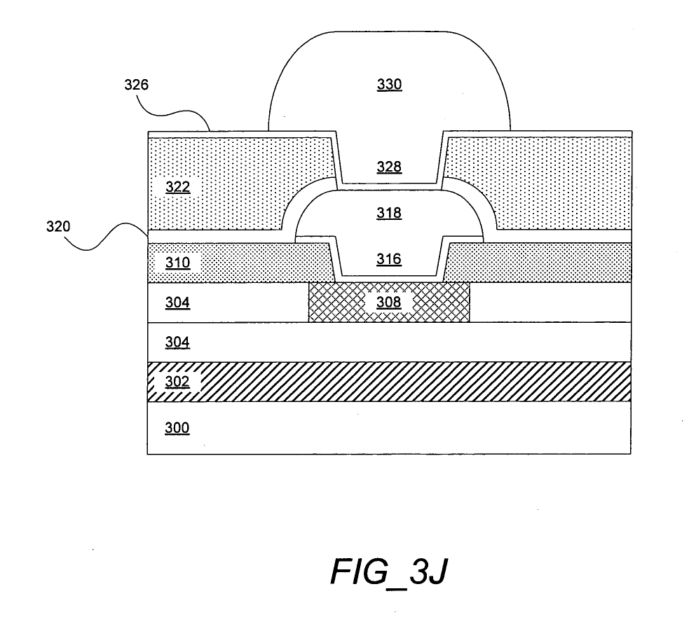

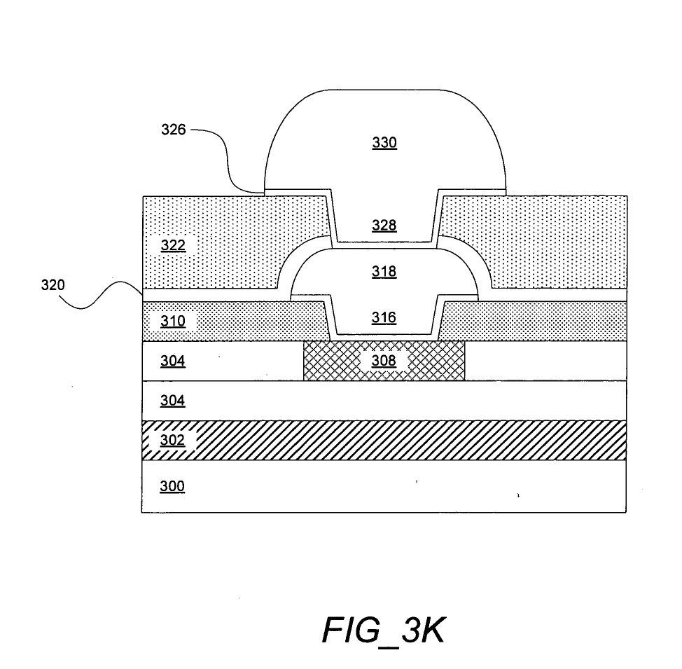

FIG. 2 is a method 200 for forming passivated redistribution interconnects in accordance with an implementation of the invention. FIGS. 3A to 3K illustrate various structures that are formed when the method 200 of FIG. 2 is carried out. The method 200 begins with providing a substrate, such as a semiconductor wafer, that includes a device layer, one or more metallization layers, at least one bond pad, and a first passivation layer (process 202 of FIG. 2). As described above, the bond pad is electrically coupled to the metallization layers. FIG. 3A illustrates a portion of a semiconductor wafer 300 that includes a device layer 302, one or more metallization layers 304, at least one bond pad 308, and a first passivation layer 310. More detailed descriptions of these layers were provided above.

The method 200 continues with an etching process to form an opening in the first passivation layer to enable the fabrication of a via for the redistribution interconnect (204 of FIG. 2). Conventional wet or dry etching processes may be used, as are well known in the art. FIG. 3B illustrates the formation of an opening 312 in the first passivation layer 310.

A BLM layer is then deposited into the etched opening (206). The deposition process used may be a plating process, such as an EP or EL plating process, a physical vapor deposition (PVD), or a vapor deposition process, such as chemical vapor deposition (CVD) or atomic layer deposition (ALD). The BLM layer may consist of one or more layers of metal, including but not limited to layers of copper, chromium, titanium, aluminum, nickel, as well as combinations or alloys of these metals. FIG. 3C illustrates a BLM layer 314 that is formed in the opening 312.

Next, a via and a redistribution interconnect are fabricated on the BLM layer (208). The via and redistribution interconnect are typically formed from a conductive metal such as copper. A plating process, such as an EP or EL plating process, may be used to form the via and the redistribution interconnect. In one implementation, as is known in the art, a photoresist material may be deposited and patterned to form a trench that is positioned over the etched opening in the first passivation layer. Copper metal may be deposited into the trench using an EP or EL plating process to form a via and a redistribution interconnect. The photoresist material may then be removed. In some implementations, a PVD, CVD, or ALD process may be used to first deposit a copper seed layer, followed by an EP or EL process to deposit a bulk layer of copper metal. FIG. 3D illustrates a via 316 and a redistribution interconnect 318 that are formed atop the BLM layer 314.

Unnecessary portions of the BLM layer that extend beyond what is required for the redistribution interconnect may be removed using an etching process after the redistribution interconnect is fabricated (210). FIG. 3E illustrates the etched BLM layer 314.

In accordance with this implementation of the invention, after the redistribution interconnect is formed, a blanket layer of a second passivation material may be deposited atop the redistribution interconnect (212). In some implementations, the second passivation material may consist of a silicon carbide having the formula SiCₓH_{y}, a nitrogen-doped silicon carbide having the formula SiCₓN_{y}H_{z}, a silicon nitride having the formula SiNₓH_{y}, or aluminum oxide (Al₂O₃). In further implementations, any other hermetic barrier layers used for copper interconnects may be used. A blanket layer of the second passivation material may be formed using processes such as CVD, ALD, EP, or EL plating. For instance, if the second passivation material consists of SiN, then a CVD process may be used with silane and ammonia as the precursors.

The second passivation material layer passivates and insulates the redistribution interconnect, thereby inhibiting copper oxidation and copper out-diffusion. The diffusion barrier functionality of the second passivation material also reduces diffusion within the redistribution interconnect, which greatly decreases electromigration issues at the surface of the redistribution interconnect. Additionally, the second passivation material tends to decrease or eliminate delamination that often occurs between the copper redistribution interconnect and the subsequently deposited ILD layer. FIG. 3F illustrates a blanket second passivation layer 320 that has been deposited over the redistribution interconnect 318.

After the redistribution interconnect has been passivated, a dielectric material may be deposited to form an ILD layer (214). As described above, many different dielectric materials may be used, including but not limited to a polymer, SiO₂ and CDO. A CVD or ALD process may be used to deposit the ILD layer. FIG. 3G illustrates an ILD layer 322 that has been formed over the second passivation layer 320 and the redistribution interconnect 318.

An etching process may then be carried out to form an opening in the ILD layer and in the second passivation layer to expose a portion of the redistribution interconnect (216). A conventional wet or dry etching process may be used, as is known in the art. In some instances, two etching processes may be used, one for the ILD layer and one for the second passivation layer. The opening may be used to form an electrical connection to couple a die-side bump to the redistribution interconnect. FIG. 3H illustrates an opening 324 that has been etched into the ILD layer 322 and the second passivation layer 320.

Once an opening has been formed in the ILD layer and the second passivation layer exposing the redistribution interconnect, a BLM layer is deposited in the opening (218). Again, the deposition process used may be an EP or EL plating process, or a PVD, CVD, or ALD process. The BLM layer may consist of one or more layers of metal, including but not limited to layers of copper, chromium, titanium, aluminum, nickel, as well as combinations or alloys of these metals. FIG. 31 illustrates a BLM layer 326 that is formed in the opening 324.

A via and a die-side bump may then be fabricated on the BLM layer (220). The via and die-side bump are typically formed from a conductive metal such as copper, a copper alloy, or Pb—Sn solder, and a plating process, such as an EP or EL plating process, is generally used to form the via and the die-side bump. In one implementation, a photoresist material may be deposited and patterned to form an opening in the photoresist layer that is positioned over the etched opening in the ILD layer and the second passivation layer. A metal may then be deposited into the opening using an EP or EL plating process to form the die-side bump, after which the photoresist layer is removed. FIG. 3J illustrates a via 328 and a die-side bump 330 that are formed atop the BLM layer 326.

Unnecessary portions of the BLM layer that extend beyond what is required for the die-side bump may be removed using an etching process after the die-side bump is fabricated (222). FIG. 3K illustrates the etched BLM layer 326. The end result is an IC chip with a passivated redistribution layer.

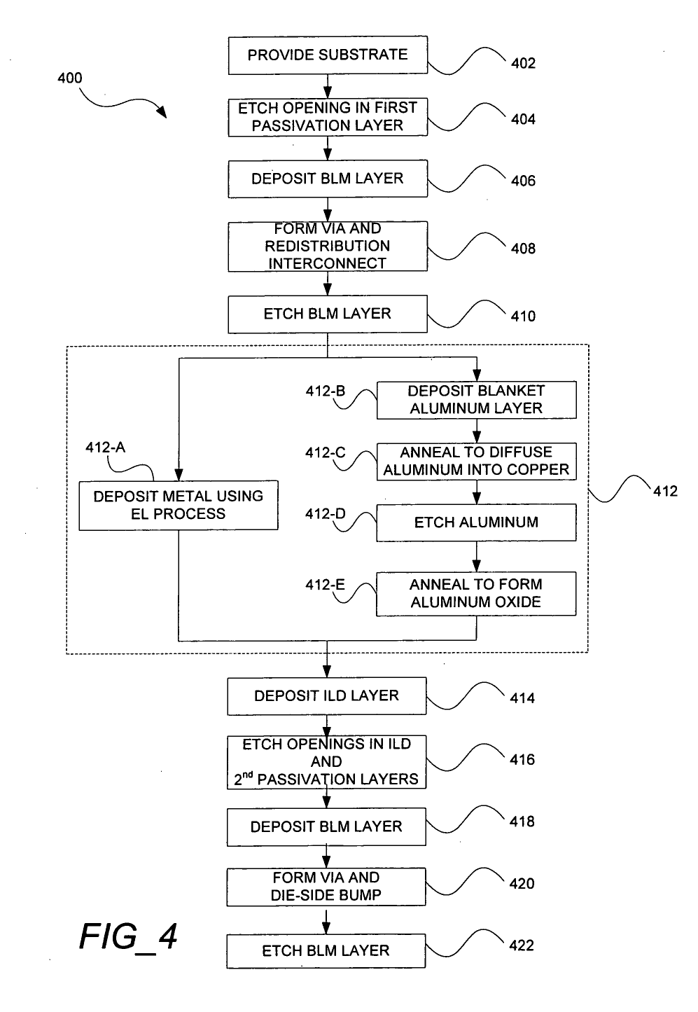

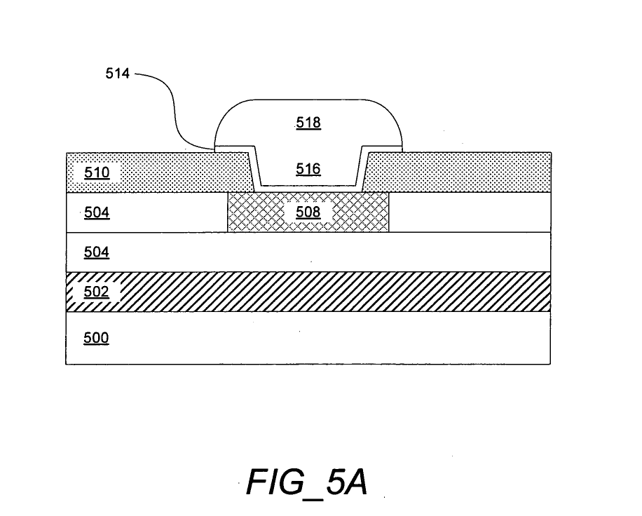

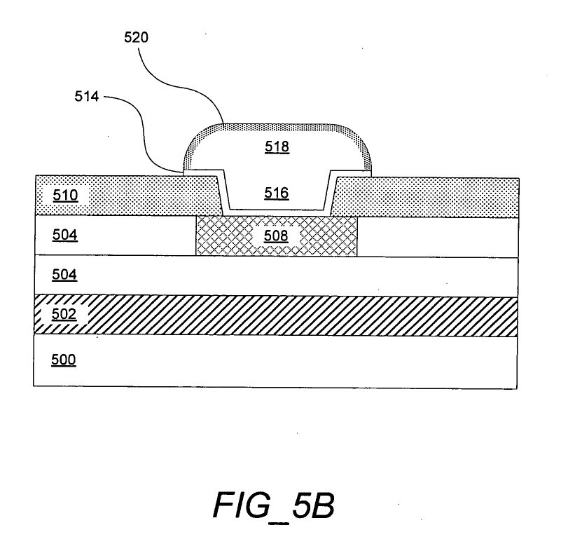

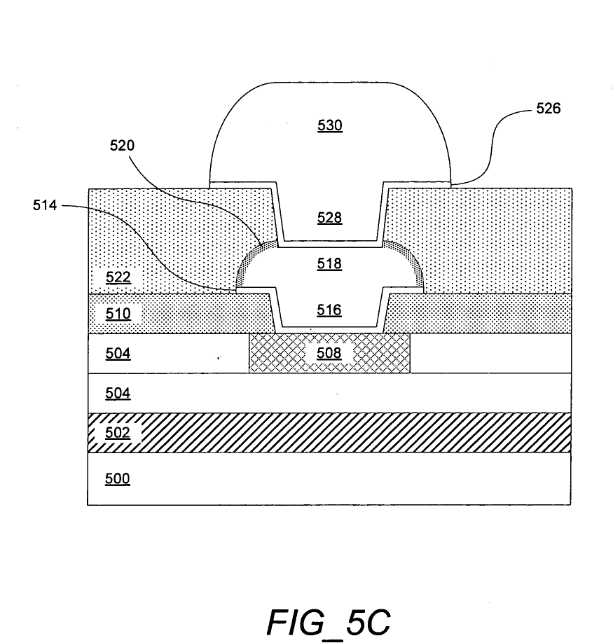

FIG. 4 is a method 400 for forming passivated redistribution interconnects in accordance with another implementation of the invention. FIGS. 5A to 5C illustrate various structures that are formed when the method 400 of FIG. 4 is carried out.

Similar to method 200 of FIG. 2, the method 400 includes providing a substrate having a device layer, one or more metallization layers, at least one bond pad, and a first passivation layer (process 402 of FIG. 4). An etching process is used to form an opening in the first passivation layer to enable the fabrication of a via for the redistribution interconnect (404). A BLM layer is then deposited into the etched opening (406), followed by the fabrication of a via and a redistribution interconnect (408). Again, the via and the redistribution interconnect are typically formed from a conductive metal such as copper and may be formed by plating copper metal into a trench formed in a photoresist layer. A copper seed layer may first be deposited to enable an EP or EL plating process. Unnecessary portions of the BLM layer that extend beyond what is required for the redistribution interconnect may then be removed (410). A wet or dry etch may be used to remove these unnecessary portions of the BLM layer.

FIG. 5A illustrates a portion of a semiconductor wafer 500 that includes a device layer 502, one or more metallization layers 504, at least one bond pad 508, and a first passivation layer 510. An opening is etched in the first passivation layer 510 where a BLM layer 514, a via 516, and a redistribution interconnect 518 are fabricated.

In accordance with this implementation of the invention, after the redistribution interconnect is formed, a second passivation layer may be selectively formed atop the redistribution interconnect (412). Unlike the blanket passivation layer described above in method 200, here the second passivation layer is selectively deposited so it is substantially limited to the surface of the redistribution interconnect. The second passivation layer may be formed using processes such as CVD, ALD, EP, or EL plating.

In one implementation, a selectively deposited second passivation layer may be formed using an EL plating process. For instance, an electroless metal such as cobalt, tungsten, or a metal alloy may be deposited to form a second passivation layer over the copper redistribution interconnect (412-A). Electroless plating is a selective deposition and occurs at activated locations on the substrate surface, i.e., locations that have a nucleation potential for an electroless plating solution. The redistribution interconnect functions as an activated location, therefore, electrolessly deposited metal tends to deposit only on the redistribution interconnect. As such, the second passivation layer is selectively deposited only on the redistribution interconnect.

In an alternate implementation of the invention, a selectively deposited second passivation layer may be formed using a blanket deposition followed by a patterning process. For example, a blanket layer of aluminum may be deposited using a physical vapor deposition process, such as a sputtering process (412-B). The aluminum metal may then undergo a first anneal to allow a portion of the aluminum metal to diffuse into the metal (e.g., copper) of the redistribution interconnect (412-C). This first anneal may takes place in an oxygen-free environment (e.g., a forming gas environment), at a temperature that ranges from 200° C. to 500° C. The blanket aluminum layer may then be patterned using a dry or wet etch to remove aluminum that extends beyond the redistribution interconnect (412-D). A second anneal may then be carried out in the presence of oxygen (e.g., in an ambient air environment) to cause an aluminum oxide layer to form on the redistribution interconnect (412-E). This second anneal may take place at a temperature that also ranges from 200° C. to 500° C. The aluminum oxide is limited to the surface of the redistribution interconnect and forms a selectively deposited second passivation layer.

As described above, the second passivation layer inhibits copper oxidation and copper out-diffusion, reduces electromigration issues at the surface of the redistribution interconnect, and decreases or eliminates delamination that often occurs between the copper redistribution interconnect and the subsequently deposited ILD layer. FIG. 5B illustrates a second passivation layer 520 that has been selectively deposited over the redistribution interconnect 518.

After the redistribution interconnect has been passivated, an ILD layer may be deposited (414). As described above, many different dielectric materials may be used, including but not limited to SiO₂, CDO, and various polymers as indicated above. An etching process may then be carried out to form openings in the ILD layer and in the second passivation layer to expose a portion of the redistribution interconnect (416). Next, a BLM layer may be deposited in the opening (418), followed by the fabrication of a via and a die-side bump on the BLM layer (420). Finally, unnecessary portions of the BLM layer that extend beyond what is required for the die-side bump may be removed using an etching process (422). The end result is an IC chip with a passivated redistribution layer.

FIG. 5C illustrates an ILD layer 522 that has been formed over the redistribution interconnect 518 and the second passivation layer 520. Also illustrated are a BLM layer 526, a via 528, and a die-side bump 530 that are fabricated within an opening in the ILD layer 522 and the second passivation layer 520.

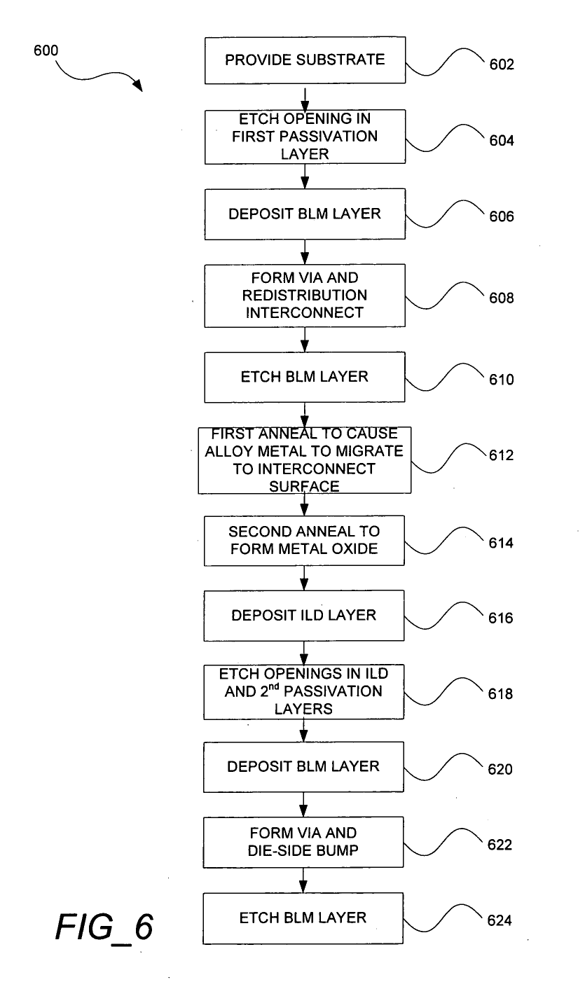

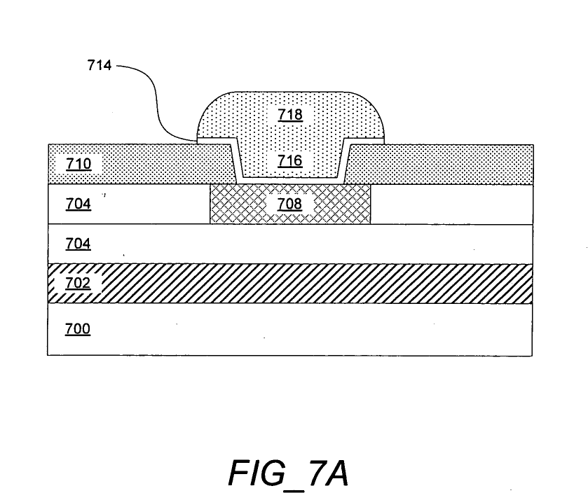

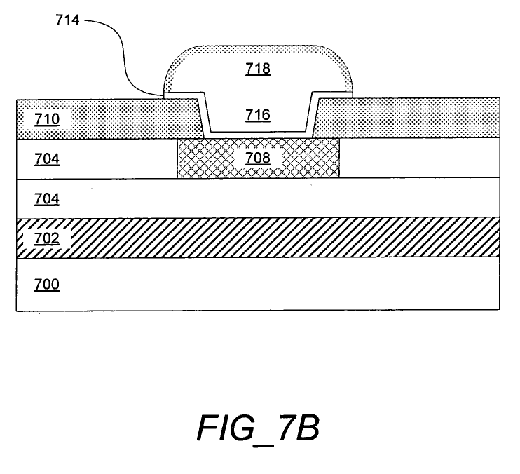

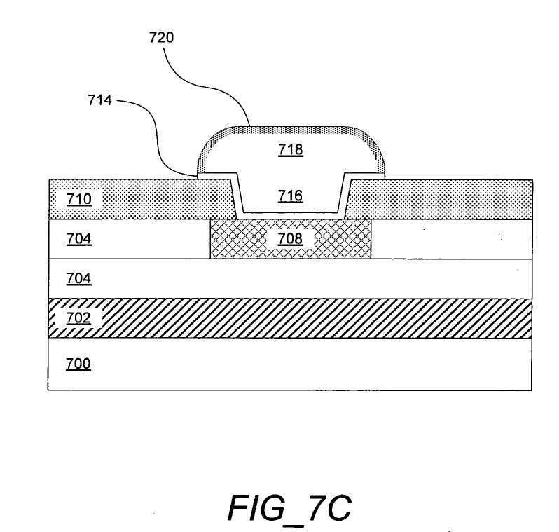

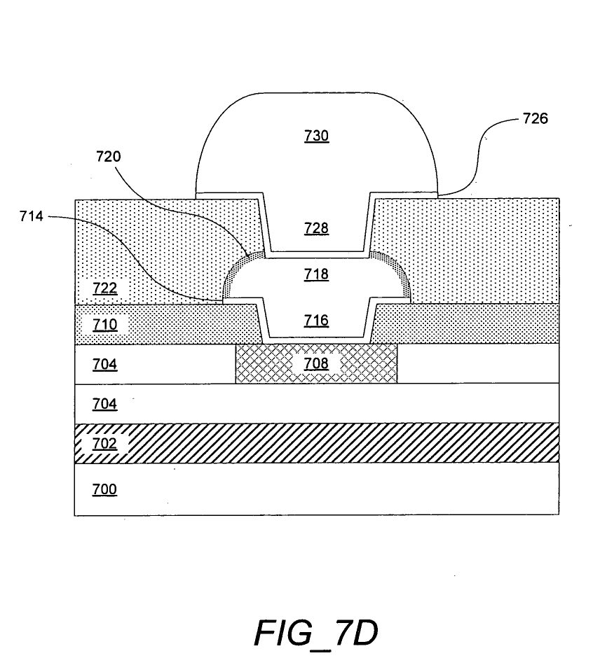

FIG. 6 is a method 600 for forming passivated redistribution interconnects in accordance with another implementation of the invention. FIGS. 7A to 7D illustrate various structures that are formed when the method 600 is carried out.

Similar to the methods described above, the method 600 includes providing a substrate having a device layer, one or more metallization layers, at least one bond pad, and a first passivation layer (process 602 of FIG. 6). An etching process is used to form an opening in the first passivation layer to enable the fabrication of a via for the redistribution interconnect (604). A BLM layer is deposited into the etched opening (606), followed by fabrication of a via and a redistribution interconnect (608). Unnecessary portions of the BLM layer that extend beyond what is required for the redistribution interconnect may then be removed (610).

Contrary to previous implementations, in this implementation the via and the redistribution interconnect include small amounts of an alloying metal in addition to the metal used to form the redistribution interconnect (e.g., copper). In one implementation, this alloying metal is a metal such as aluminum, tin, magnesium, or cobalt that is introduced in the bulk metal deposition of the via and the redistribution interconnect. In other words, after a copper seed layer had been deposited, the EP or EL plating process used to deposit the via and the redistribution interconnect plates both copper and the alloying metal. In another implementation of the invention, the alloying metal is introduced by way of a copper-alloy seed layer. Here, the copper-alloy seed layer includes copper combined with aluminum, tin, or magnesium while the bulk deposition process generally uses only copper metal. In various implementations, the concentration of alloying metal within the copper redistribution layer may range from 0.001% to 1.0%.

FIG. 7A illustrates a portion of a semiconductor wafer 700 that includes a device layer 702, one or more metallization layers 704, at least one bond pad 708, and a first passivation layer 710. An opening is etched in the first passivation layer 710 where a BLM layer 714, a via 716, and a redistribution interconnect 718 are fabricated. In this implementation, the metal used in the via 716 and the redistribution interconnect 718 may be copper metal that includes an alloying metal such as aluminum, tin, magnesium, or cobalt.

In accordance with this implementation of the invention, after the redistribution interconnect is formed, a second passivation layer may be formed by causing the alloying metal to segregate to the surface of the redistribution interconnect and form a metal oxide. Unlike the blanket passivation layer described above, here the second passivation layer is a selectively formed layer that is substantially limited to the surface of the redistribution interconnect.

To form the second passivation layer, a first annealing process is carried out in an oxygen-free atmosphere to cause the alloying metal to migrate towards the surface of the redistribution interconnect (612). The alloying metals used here have a tendency to segregate to free surfaces to form an oxide or nitride passivation layer. In some implementations of the invention, the annealing parameters for this oxygen-free anneal include a temperature that ranges from 200° C. to 500° C. for a time period that ranges from 100 seconds to 100 minutes. FIG. 7B illustrates the migration of the alloying metal to the surface of the redistribution interconnect 718.

When the alloying metal is proximate to the surface of the redistribution interconnect, a second annealing process may then be carried out in the presence of oxygen or nitrogen (614). For instance, the second annealing may take place in the presence of ambient air. This second anneal causes the alloying metal to combine with oxygen or nitrogen to form a metal oxide or metal nitride that functions as a second passivation layer for the redistribution interconnect. For instance, in some implementations the second passivation layer may consist of aluminum oxide, aluminum nitride, tin oxide, tin nitride, magnesium oxide, magnesium nitride, cobalt oxide, or cobalt nitride. In some implementations of the invention, the annealing parameters for this second anneal include a temperature that ranges from 200° C. to 500° C. for a time period that ranges from 100 seconds to 100 minutes.

As described above, the second passivation layer inhibits copper oxidation and copper out-diffusion, reduces electromigration issues at the surface of the redistribution interconnect, and decreases or eliminates delamination that often occurs between the copper redistribution interconnect and the subsequently deposited ILD layer. FIG. 7C illustrates a second passivation layer 720 that has been formed over the redistribution interconnect 718.

After the redistribution interconnect has been passivated, an ILD layer may be deposited (616). An etching process may then be carried out to form an opening in the ILD layer and in the second passivation layer to expose a portion of the redistribution interconnect (618). Next, a BLM layer may be deposited in the opening (620), followed by the fabrication of a via and a die-side bump on the BLM layer (622). Finally, unnecessary portions of the BLM layer that extend beyond what is required for the die-side bump may be removed using an etching process (624). The end result is an IC chip with a passivated redistribution layer.

FIG. 7D illustrates an ILD layer 722 that has been formed over the redistribution interconnect 718 and the passivation layer 720. Also illustrated are a BLM layer 726, a via 728, and a die-side bump 730 that are fabricated within an opening in the ILD layer 722 and the passivation layer 720.

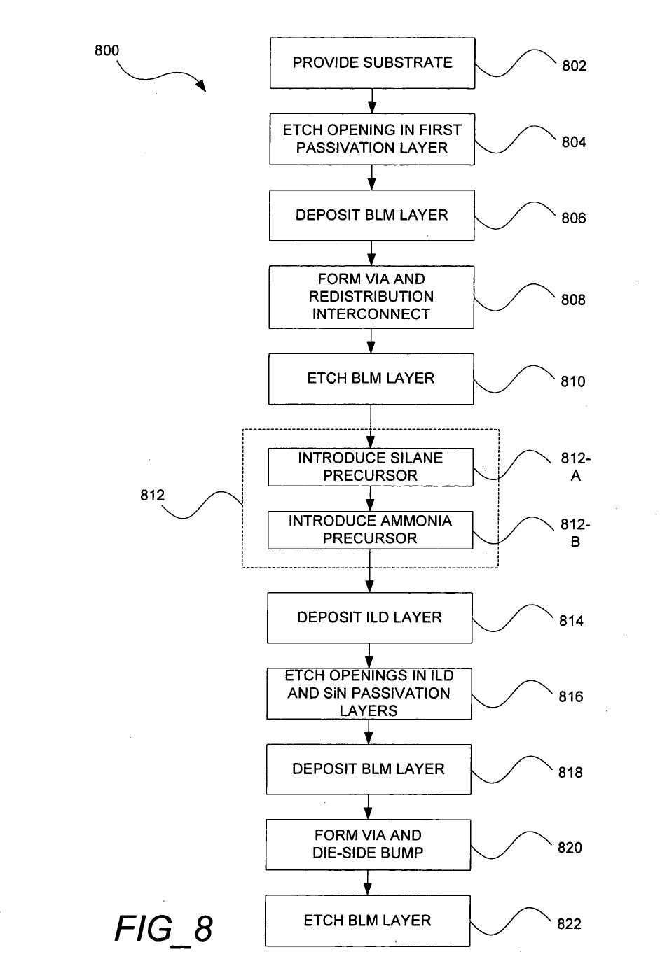

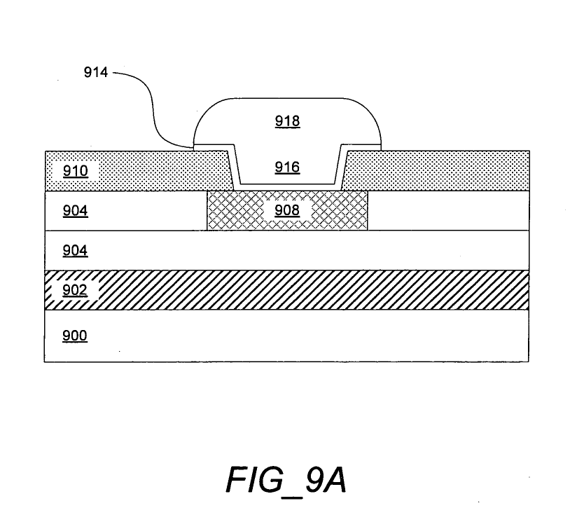

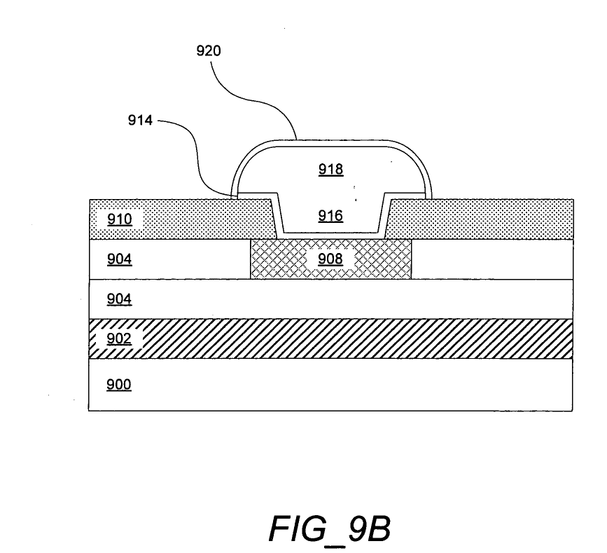

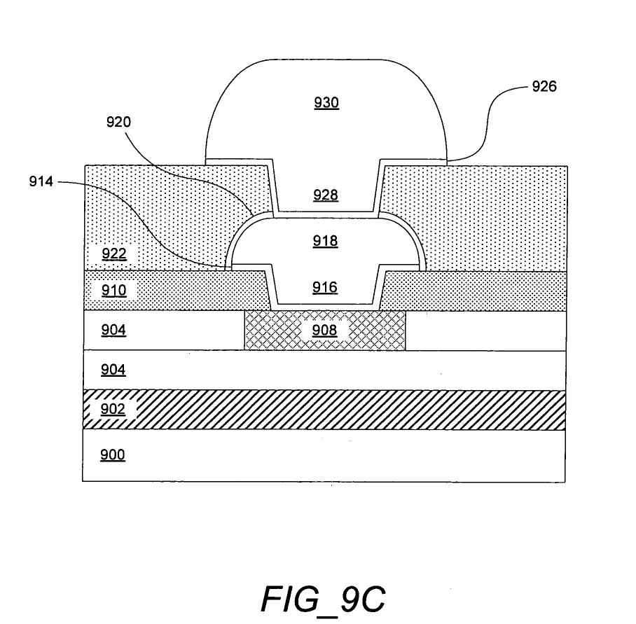

FIG. 8 is a method 800 for forming passivated redistribution interconnects in accordance with another implementation of the invention. FIGS. 9A to 9C illustrate various structures that are formed when the method 800 is carried out.

Similar to the methods described above, the method 800 includes providing a substrate having a device layer, one or more metallization layers, at least one bond pad, and a first passivation layer (process 802 of FIG. 8). An etching process is used to form an opening in the first passivation layer to enable the fabrication of a via for the redistribution interconnect (804). A BLM layer is deposited into the etched opening (806), followed by fabrication of a via and a redistribution interconnect (808). In this implementation, the via and the redistribution interconnect are formed using copper metal. Unnecessary portions of the BLM layer that extend beyond what is required for the redistribution interconnect are then removed (810). A wet or dry etch may be used to remove these unnecessary portions of the BLM layer.

FIG. 9A illustrates a portion of a semiconductor wafer 900 that includes a device layer 902, one or more metallization layers 904, at least one bond pad 908, and a first passivation layer 910. An opening is etched in the first passivation layer 910 where a BLM layer 914, a via 916, and a redistribution interconnect 918 are fabricated.

In accordance with this implementation of the invention, after the redistribution interconnect is formed, a silicon nitride passivation layer may be selectively deposited atop the redistribution interconnect (812). Unlike the blanket silicon nitride passivation layer described above in method 200, here the silicon nitride layer is formed in a manner that substantially limits its deposition to the surface of the redistribution interconnect without requiring a subsequent etching process.

In one implementation, a selectively deposited silicon nitride layer may be formed using a vapor deposition process. Selectivity is achieved by first introducing a silane precursor to form a salicide and then separately introducing an ammonia precursor to convert the salicide into the silicon nitride. In one implementation, the silane precursor is introduced at a low temperature, for instance around 200° C., where it reacts with the copper metal to form a layer of copper salicide on the copper redistribution interconnect (812-A). The use of a low temperature minimizes the diffusion of silicon into the copper, thereby mitigating any adverse effect the silicon has on the line resistance of the copper interconnect. Next, the ammonia precursor is introduced at a high temperature to convert the copper salicide into silicon nitride (812-B). The high temperature may range from 350° C. to 450° C. FIG. 9B illustrates a silicon nitride passivation layer 920 that has been formed over the redistribution interconnect 918.

After the redistribution interconnect has been passivated, an ILD layer may be deposited (814). An etching process may then be carried out to form an opening in the ILD layer and in the silicon nitride passivation layer to expose a portion of the redistribution interconnect (816). Next, a BLM layer may be deposited in the opening (818), followed by the fabrication of a via and a die-side bump on the BLM layer (820). Finally, unnecessary portions of the BLM layer that extend beyond what is required for the die-side bump may be removed using an etching process (822). The end result is an IC chip with a passivated redistribution layer.

FIG. 9C illustrates an ILD layer 922 that has been formed over the redistribution interconnect 918 and the silicon nitride passivation layer 920. Also illustrated are a BLM layer 926, a via 928, and a die-side bump 930 that are fabricated within an opening in the ILD layer 922 and the silicon nitride passivation layer 920.

Accordingly, methods have been disclosed herein that enable improved adhesion between the copper redistribution interconnect and the ILD layer through the use of a intermediary passivation layer. The passivation layer substantially reduces the occurrence of delamination that is often observed at the copper/ILD interface. The use of a passivation layer also improves electromigration performance and functions as a barrier to prevent copper diffusion into the ILD layer.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a substrate having one or more metallization layers;
a redistribution interconnect electrically coupled to at least one of the metallization layers; and
a passivation layer formed on the redistribution interconnect.

2. The apparatus of claim 1, further comprising a die-side bump electrically coupled to the redistribution interconnect.

3. The apparatus of claim 1, wherein the substrate comprises a semiconductor substrate having a plurality of devices formed thereon, wherein the one or more metallization layers interconnect the plurality of devices.

4. The apparatus of claim 1, wherein the redistribution interconnect is formed above the one or more metallization layers.

5. The apparatus of claim 2, wherein the die-side bump is electrically coupled to the redistribution interconnect through an opening formed in the passivation layer.

6. The apparatus of claim 1, wherein the redistribution interconnect is electrically coupled to at least one of the metallization layers by way of a bond pad.

7. The apparatus of claim 1, wherein the passivation layer comprises at least one of silicon carbide, a silicon carbide having the formula SiCₓH_{y}, a nitrogen-doped silicon carbide having the formula SiCₓN_{y}H_{z}, silicon nitride, a silicon nitride having the formula SiNₓH_{y}, cobalt, tungsten, or a metal alloy.

8. The apparatus of claim 1, wherein the passivation layer comprises a metal oxide.

9. The apparatus of claim 8, wherein the metal oxide comprises aluminum oxide, tin oxide, magnesium oxide, or cobalt oxide.

10. The apparatus of claim 1, wherein the passivation layer comprises a metal nitride.

11. The apparatus of claim 10, wherein the passivation layer comprises aluminum nitride, tin nitride, magnesium nitride, or cobalt nitride.

12. The apparatus of claim 1, wherein the redistribution layer comprises copper metal.

13. The apparatus of claim 1, wherein the die-side bump may be used in a C4 packaging process.

14. An apparatus comprising:
a semiconductor substrate having a plurality of devices formed thereon;
one or more metallization layers to interconnect the plurality of devices;
a bond pad formed over the one or more metallization layers and electrically coupled to at least one of the metallization layers;
a first passivation layer formed over the bond pad and over the one or more metallization layers;
a redistribution interconnect formed on the first passivation layer;
a first via formed through the first passivation layer to electrically couple the redistribution interconnect to the bond pad;
a second passivation layer formed on the redistribution interconnect;
a dielectric layer formed on the second passivation layer;
a die-side bump formed on the dielectric layer; and
a second via formed through the dielectric layer and through the second passivation layer to electrically couple the die-side bump to the redistribution interconnect.

15. The apparatus of claim 14, wherein the first passivation layer comprises silicon nitride, oxynitride, polyimide, or a polymer.

16. The apparatus of claim 14, wherein the redistribution interconnect comprises copper.

17. The apparatus of claim 14, wherein the second passivation layer comprises at least one of silicon carbide, a silicon carbide having the formula SiCₓH_{y}, a nitrogen-doped silicon carbide having the formula SiCₓN_{y}H_{z}, silicon nitride, a silicon nitride having the formula SiNₓH_{y}, cobalt, tungsten, or a metal alloy.

18. The apparatus of claim 14, wherein the second passivation layer comprises a metal oxide.

19. The apparatus of claim 18, wherein the metal oxide comprises aluminum oxide, tin oxide, magnesium oxide, or cobalt oxide.

20. The apparatus of claim 14, wherein the second passivation layer comprises a metal nitride.

21. The apparatus of claim 20, wherein the metal nitride comprises aluminum nitride, tin nitride, magnesium nitride, or cobalt nitride.

22. The apparatus of claim 14, further comprising a base layer metallurgy formed within the first via and beneath the redistribution interconnect.

23. The apparatus of claim 14, further comprising a base layer metallurgy formed within the second via and beneath the die-side bump.

24. A method comprising:
forming a metal redistribution interconnect on a semiconductor substrate; and
forming a passivation layer on the metal redistribution interconnect.

25. The method of claim 24, wherein the semiconductor substrate comprises:
a device layer;
one or more metallization layers;
a bond pad electrically coupled to at least one metallization layer and electrically coupled to the metal redistribution interconnect; and
a second passivation layer over the bond pad, wherein the metal redistribution interconnect is formed on the second passivation layer.

26. The method of claim 24, wherein the forming of the passivation layer on the metal redistribution interconnect comprises depositing a blanket layer of a passivation material.

27. The method of claim 26, wherein the passivation material comprises at least one of silicon carbide, a silicon carbide having the formula SiCₓH_{y}, a nitrogen-doped silicon carbide having the formula SiCₓN_{y}H_{z}, silicon nitride, or a silicon nitride having the formula SiNₓH_{y}.

28. The method of claim 24, wherein the forming of the passivation layer on the metal redistribution interconnect comprises a selective deposition of a passivation material that is limited to a surface of the metal redistribution interconnect.

29. The method of claim 28, wherein the selective deposition of the passivation material comprises electrolessly depositing a metal layer on the metal redistribution interconnect.

30. The method of claim 29, wherein the metal layer comprises cobalt, tungsten, or a metal alloy.

31. The method of claim 28, wherein the selective deposition of the passivation material comprises:
depositing a blanket metal layer over the metal redistribution interconnect; and
removing portions of the metal layer sited beyond a surface of the metal redistribution interconnect.

32. The method of claim 31, wherein the metal comprises aluminum.

33. The method of claim 24, wherein the metal redistribution interconnect includes an alloying metal and wherein the forming of the passivation layer on the metal redistribution interconnect comprises:
annealing the metal redistribution interconnect in an oxygen-free atmosphere to cause the alloying metal to diffuse to a surface of the metal redistribution interconnect; and
annealing the metal redistribution interconnect in an oxygen-containing atmosphere to cause the alloying metal to form a metal oxide.

34. The method of claim 33, wherein the alloying metal comprises at least one of aluminum, tin, magnesium, or cobalt.

35. The method of claim 33, wherein the forming of the metal redistribution interconnect comprises:
depositing a seed layer on the semiconductor substrate, wherein the seed layer includes the alloying metal; and
depositing the metal redistribution interconnect on the seed layer.

36. The method of claim 24, wherein the metal redistribution interconnect includes an alloying metal and wherein the forming of the passivation layer on the metal redistribution interconnect comprises:
annealing the metal redistribution interconnect in an oxygen-free atmosphere to cause the alloying metal to diffuse to a surface of the metal redistribution interconnect; and
annealing the metal redistribution interconnect in a nitrogen-containing atmosphere to cause the alloying metal to form a metal nitride.

37. The method of claim 36, wherein the alloying metal comprises at least one of aluminum, tin, magnesium, or cobalt.

38. The method of claim 36, wherein the forming of the metal redistribution interconnect comprises:
depositing a seed layer on the semiconductor substrate, wherein the seed layer includes the alloying metal: and
depositing the metal redistribution interconnect on the seed layer.

39. The method of claim 24, wherein the forming of the passivation layer on the metal redistribution interconnect comprises:
introducing a silane into a reactor housing the substrate to react and form a metal salicide on a surface of the metal redistribution interconnect; and
introducing an ammonia plasma into the reactor to react with the metal salicide and form a silicon nitride layer on the surface of the metal redistribution interconnect.

40. The method of claim 39, wherein the ammonia plasma is introduced into the reactor at a temperature around 400° C.

41. The method of claim 39, wherein the silane is introduced into the reactor at a low enough temperature to minimize silicon diffusion into the metal redistribution interconnect.
